(19) United States
(12) Patent Application Publication
(10) Pub. No.: US 2025/0190338 A1
(43) Pub. Date: Jun. 12, 2025

(54) MEMORY DEVICE AND METHOD OF OPERATING THE SAME

(71) Applicant: SAMSUNG ELECTRONICS CO., LTD., SUWON-SI (KR)

(72) Inventors: SANGHOON CHA, SUWON-SI (KR); YOONAH PAIK, SUWON-SI (KR); SUNJUNG LEE, SUWON-SI (KR)

(21) Appl. No.: 18/975,836

(22) Filed: Dec. 10, 2024

(30) Foreign Application Priority Data
Dec. 11, 2023 (KR) 10-2023-0178634

(51) Int. Cl. G06F 12/02

(52) U.S. Cl. CPC G06F 12/0223

(57) ABSTRACT

A memory device and a method of operating the same are provided. The memory device includes an operation module including a plurality of operators configured to perform a data operation, a register configured to store a plurality of pieces of data, and a selection module configured to receive an operation mode input and map the plurality of pieces of data stored in the register to the plurality of operators based on the operation mode input.

### CROSS-REFERENCE TO RELATED APPLICATION

This application claims priority under 35 U.S.C. § 119 to Korean Patent Application No. 10-2023-0178634, filed on Dec. 11, 2023, the disclosure of which is incorporated by reference herein in its entirety.

### TECHNICAL FIELD

Embodiments of the invention relate to a memory device and a method of operating the same.

### DISCUSSION OF RELATED ART

The utilization of deep neural networks (DNNs) is leading to an industrial revolution based on artificial intelligence (AI). A convolutional neural network (CNN), which is a type of DNN, is widely used in various application fields such as, for example, image and signal processing, object recognition, computer vision, and the like that mimic the human optic nerve. The CNN may be configured to perform a multiply and accumulate (MAC) operation that repeats multiplication and addition using a considerably large number of matrices. When an application of a CNN is executed using general-purpose processors, an operation that utilizes a considerable amount of computations but is not complex, such as, for example, a MAC operation that calculates an inner product of two vectors and accumulates and sums the values, may be performed through processing in memory (PIM).

### SUMMARY

According to an aspect, there is provided a memory device for supporting a data operation according to a plurality of operation modes, the memory device including an operation module including a plurality of operators configured to perform the data operation, a register configured to store a plurality of pieces of data, and a selection module configured to receive an operation mode input and map the plurality of pieces of data stored in the register to the plurality of operators based on the operation mode input.

The selection module may be further configured to select a plurality of partial pieces of data from among the plurality of pieces of data stored in the register based on the operation mode input and map the partial pieces of data to the plurality of operators.

The selection module may be further configured to map each of the plurality of partial pieces of data to a different set of operators based on the first operation mode input.

A number of operators included in the set of operators may be variable based on the first operation mode input.

The selection module may be further configured to map any one of the plurality of pieces of data stored in the register to the plurality of operators based on the operation mode input.

The selection module may be further configured to map the plurality of pieces of data stored in the register to the plurality of operators in a one-to-one manner based on the operation mode input.

The memory device may further include a memory bank, and the operation module may be configured to perform an operation between data stored in the memory bank and the plurality of pieces of data stored in the register mapped by the selection module.

The memory bank may be configured to store matrix data, the register may be configured to store a plurality of pieces of vector data, and the operation module may be configured to perform a multiply and accumulate (MAC) operation between the matrix data and the plurality of pieces of vector data.

The plurality of operation modes may be determined based on at least one of a dimension of the matrix data, a dimension of the plurality of pieces of vector data, or a number of the plurality of operators included in the operation module.

The memory bank may be configured to store weight data of an artificial neural network model, and the register may be configured to store input data of the artificial neural network model.

The memory device may further include an instruction register configured to store an instruction instructing the plurality of operation modes, and the selection module may be further configured to receive the instruction from the instruction register.

The memory device may further include a memory controller configured to transmit an instruction instructing the plurality of operation modes to the selection module.

The plurality of pieces of data stored in the register may be divided into a plurality of parts, and the selection module may include a plurality of first multiplexers configured to output, for each of the plurality of parts, any one of pieces of data included in a corresponding part, and a plurality of second multiplexers configured to be mapped to each of the plurality of operators, where, for each of the second multiplexers, a corresponding second multiplexer is configured to output any one of pieces of data received from the first multiplexers to an operator mapped to the corresponding second multiplexer.

The memory device may be implemented as one of a high bandwidth memory (HBM) device, a double data rate (DDR) device, a low-power double data rate (LPDDR) device, or a graphics double data rate (GDDR) device.

According to an aspect, there is provided a memory device including an operation module including a plurality of operators configured to perform a data operation, a memory bank configured to store matrix data, a register configured to store a plurality of pieces of vector data, and a selection module configured to select a plurality of partial pieces of data from among the plurality of pieces of vector data stored in the register and map the partial pieces of data to the plurality of operators, based on a dimension of the matrix data and a number of the plurality of operators included in the operation module.

According to an aspect, there is provided a method of operating a memory device for supporting a data operation according to a plurality of operation modes, the method including receiving an operation mode input, mapping a plurality of pieces of data stored in a register to a plurality of operators based on the operation mode input, and performing an operation between data stored in a memory bank and the plurality of pieces of data stored in the register and mapped by a selection module.

The mapping of the plurality of pieces of data to the plurality of operators may include selecting a plurality of partial pieces of data from among the plurality of pieces of data stored in the register based on the operation mode input and mapping the partial pieces of data to the plurality of operators.

The mapping of the plurality of pieces of data to the plurality of operators may include mapping any one of the plurality of pieces of data stored in the register to the plurality of operators based on the operation mode input.

The mapping of the plurality of pieces of data to the plurality of operators may include mapping the plurality of pieces of data stored in the register to the plurality of operators in a one-to-one manner based on the operation mode input.

The mapping of the plurality of pieces of data to the plurality of operators may include receiving an instruction from an instruction register configured to store the instruction instructing the plurality of operation modes.

The mapping of the plurality of pieces of data to the plurality of operators may include receiving an instruction instructing the plurality of operation modes from a memory controller.

### BRIEF DESCRIPTION OF THE DRAWINGS

The above and other features of the present invention will become more apparent by describing in detail embodiments thereof with reference to the accompanying drawings, in which:

FIG. 1 illustrates a computing system according to an embodiment;

FIG. 2 illustrates a processing in memory (PIM) block according to an embodiment;

FIG. 3 illustrates a general matrix vector multiplication (GEMV) operation processed by a computing system according to an embodiment;

FIGS. 4A to 4C are diagrams illustrating an operation mode according to an embodiment;

FIG. 5A is a diagram illustrating a method of controlling an operation mode according to a PIM instruction set architecture (ISA) method according to an embodiment;

FIG. 5B is a diagram illustrating a method of controlling an operation mode according to a method of adding an instruction to a memory controller according to an embodiment;

FIGS. 6A to 6D are diagrams illustrating an example of a selection module according to an embodiment;

FIG. 7 is a flowchart illustrating a method of operating a memory device according to an embodiment;

FIG. 8 is a graph illustrating performance of a memory device according to an embodiment; and

FIG. 9 illustrates a high bandwidth memory (HBM) device according to an embodiment.

### DETAILED DESCRIPTION

Embodiments of the present invention will be described more fully hereinafter with reference to the accompanying drawings. Like reference numerals may refer to like elements throughout the accompanying drawings.

It should be understood that the terms “comprises” and/or “comprising,” when used in this specification, specify the presence of stated features, integers, steps, operations, elements, components or a combination thereof, but do not preclude the presence or addition of one or more other features, integers, steps, operations, elements, components, and/or groups thereof.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

It will be understood that when a component such as a film, a region, a layer, etc., is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

The examples may be implemented as various types of products such as, for example, a personal computer, a laptop computer, a tablet computer, a smart phone, a television, a smart home appliance, an intelligent vehicle, a kiosk, and a wearable device.

Embodiments of the present invention provide a memory device and method of operating the same, in which the memory device is designed to handle data operations efficiently in various operation modes. For example, a memory device may include an operation module with multiple operators that perform data operations, a register for storing data, and a selection module that maps data from the register to the operators based on an operation mode input.

According to embodiments of the present invention, a memory device may support multiple operation modes, which allow for different data processing strategies depending on the mode selected. For example, a selection module can map all or part of the data to the operators differently based on the input mode.

Embodiments of the present invention may provide the ability to handle matrix and vector data, which may be particularly useful for operations like multiply and accumulate (MAC), often utilized in neural network computations. Embodiments of the present invention may further provide versatility in handling different types of memory data, such as weights and inputs for neural networks. Embodiments of the present invention may further provide adaptability to various memory types, including, for example, high-bandwidth memory (HBM), double data rate (DDR), and others, making it suitable for a wide range of computing devices from personal computers to intelligent vehicles and smart home appliances.

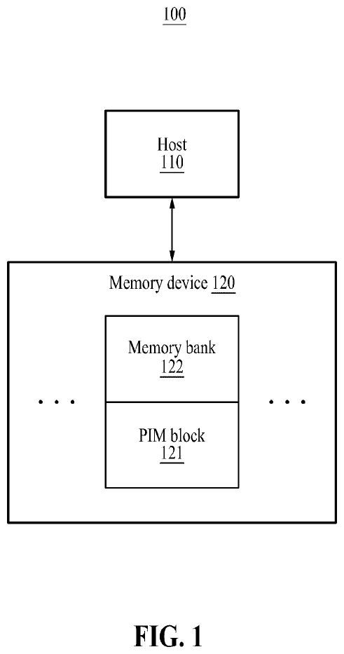

FIG. 1 illustrates a computing system according to an embodiment.

A computing system 100 according to an embodiment may include a host 110 and a memory device 120.

The host 110 may be a main management entity of a computer system (e.g., an electronic device) and may be implemented as a host processor or a server. The host processor may include, for example, a host central processing unit (CPU). For example, the host processor may include a processor core and a memory controller. The memory controller may control the memory device 120. The host processor may process data received from the memory device 120 through the memory controller using a processor core. In addition, the memory controller may transmit a command to the memory device 120. Here, examples of a write command and an operation command are mainly described as commands transmitted to the memory device 120.

As an example, the write command may be a command instructing to write an input value for a target operation (e.g., a multiply and accumulate (MAC) operation) to a register file of the memory device 120. The operation command may be a command instructing an operation for a matrix product (e.g., a general matrix vector multiplication (GEMV) operation) between parts of some weight matrices (or weight vectors) of an input vector. As described below, a processing in memory (PIM) block 121 of the memory device 120 may perform a multiplication operation between an input value and weight values and an addition operation of partial operation results based on the operation command. For example, the operation command may be a dynamic random-access memory (DRAM) command provided to the memory device 120. A DRAM RD command of the DRAM command may correspond to an operation command and a DRAM WR command may correspond to a write command. Each operation command may include information (e.g., address information) indicating an internal address of the memory device 120.

The memory device 120 may include a memory area that stores data. The memory area may refer to an area (e.g., a physical area) where data may be read from and/or written in a memory chip of the physical memory device, that is, the memory device 120. As described below, the memory area may be disposed in a memory die (or a core die) of the memory device 120. The memory device 120 may process data of the memory area in cooperation with the host processor. For example, the memory device 120 may perform an operation or processing of data based on a command or instruction received from the host processor. The memory device 120 may control the memory area in response to the command or instruction of the host processor. The memory device 120 may be separated from the host processor. For example, the host processor may direct all operations and delegate an operation utilizing acceleration (e.g., a PIM) to the memory device 120.

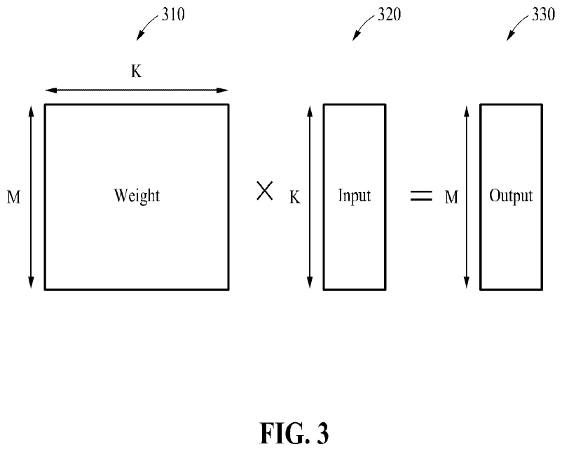

The memory device 120 may include the PIM block 121 and a memory (e.g., a plurality of memory banks 122). For example, the memory device 120 may perform a target operation using data stored in the memory through a plurality of PIM blocks 121. The target operation may be, for example, a GEMV operation. For example, input data and output data of the GEMV operation may be data in the form of a vector, and weight data may be data in the form of a matrix. Since the weight data has a capacity (e.g., a memory size) larger than the cache size of the host 110, the weight data may be stored in the memory device 120 (e.g., a DRAM device). As described in more detail with reference to FIG. 3, the GEMV operation may be, for example, an operation between a weight matrix and an input vector (e.g., a matrix-vector multiplication operation).

The memory may store data. The plurality of memory banks 122 may be generated using a portion or all of memory chips of the memory device 120. In the present specification, each of the plurality of memory banks 122 may store values to be used in a target operation.

Each memory bank 122 may include a plurality of storage cells that store values in a memory array disposed on a memory die of the memory device 120. The plurality of storage cells may be arranged along a row line and a column line. A portion including storage cells arranged along an arbitrary row line in the memory bank 122 may be referred to as a memory row. The memory row may be a group of storage cells arranged along the same row line. Similarly, a memory column may be a group of storage cells arranged along the same column line.

The PIM block 121 may perform an operation using data stored in the memory according to the operation command. The PIM block 121 may load weight data and input data corresponding to the operation command and perform a multiplication operation and/or addition operation using the loaded data.

For example, FIG. 1 illustrates an example in which the PIM block 121 is allocated to one memory bank 122 in a core die, but embodiments are not limited thereto. The PIM block 121 may be disposed adjacent to the plurality of memory banks 122 (e.g., two memory banks 122) and may be accessible.

As described above, the PIM block 121 may load weight data from the memory bank 122 and may load input data from a register. The PIM block 121 may perform an operation between the loaded weight data and the input data using MAC units.

Instructions may include instructions to execute operations of the host processor, the memory device 120, or processors in various devices, and/or operations of each component of a processor. For example, instructions (or programs) executable by the host processor may be stored in another memory device 120, but embodiments are not limited thereto. In addition, an instruction may include an operation mode instruction. The PIM block 121 may operate in a plurality of operation modes, and an operation mode instruction may be an instruction indicating any one of the plurality of operation modes.

The memory device 120 (e.g., a PIM device) including the PIM block 121 may perform an operation for acceleration of an application program (e.g., machine learning and big data) that utilizes a large memory bandwidth. The memory device 120 may increase utilization of MAC units by operating in the plurality of operation modes through the plurality of PIM blocks 121.

The memory device 120 (e.g., a PIM device) may perform additional acceleration on the PIM block 121 by maximizing bank-level parallelism by using an increase in an internal memory bandwidth of the PIM block 121. The memory device may also be referred to as a memory device circuit.

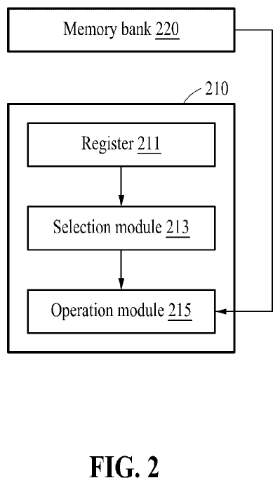

FIG. 2 illustrates a PIM block according to an embodiment.

Referring to FIG. 2, a PIM block 210 according to an embodiment may include a register 211 (also referred to herein as a register circuit), a selection module 213 (also referred to herein as a selection circuit or a selection module circuit), and an operation module 215 (also referred to herein as an operation circuit or an operation module circuit). As described above, the PIM block 210 may be disposed adjacent to a corresponding memory bank 220 among a plurality of memory banks of a memory device. The PIM block 210 may access the adjacent memory bank 220 through a bank interface. The memory bank 220 may store matrix data (e.g., weight data) as described above.

The register 211 according to an embodiment may include a plurality of elements (e.g., “N” elements, where N is a positive integer). The register 211 may store vector data (e.g., input data) as described above, and components of the vector data may be stored in each element of the register 211.

The operation module 215 may include a plurality of operators (e.g., “N” operators). An operator may be, for example, a MAC unit. The number of operators is the same as dividing a unit read from the memory bank 220 by the magnitude of the element. For example, when the read unit of the memory bank 220 is 256 bits, when using an 8-bit number system of INT8, the magnitude of the element is 8 bits and the number of MAC units of the operation module 215 may be 32. Alternatively, when using a 16-bit number system of FP16, the magnitude of the element may be 16 bits and the number of MAC units of the operation module 215 may be 16. However, the number of MAC units is not limited to the above-described examples and may vary depending on the design.

As described in detail below, the memory device may support a data operation according to a plurality of operation modes through the selection module 213. The selection module 213 may receive an operation mode input and may map a plurality of pieces of data stored in the register 211 to the plurality of operators of the operation module 215 based on the operation mode input. The operation module 215 may perform an operation (e.g., a GEMV operation) between data stored in the memory bank 220 and the plurality of pieces of data stored in the register 211 mapped by the selection module 213.

FIG. 3 illustrates a GEMV operation processed by a computing system according to an embodiment.

The computing system according to an embodiment may perform the GEMV operation as a target operation. The GEMV operation may be a matrix multiplication operation between a matrix and a vector, as shown in FIG. 3. For example, a weight matrix 310 may be a matrix of dimension M×K, an input vector 320 may be a vector of dimension K×1, and an output vector 330 may be a vector of dimension M×1. M and K may each be an integer greater than 1, where K may be an input dimension and M may be an output dimension. For example, in the present specification, a dimension may be expressed as the number of elements.

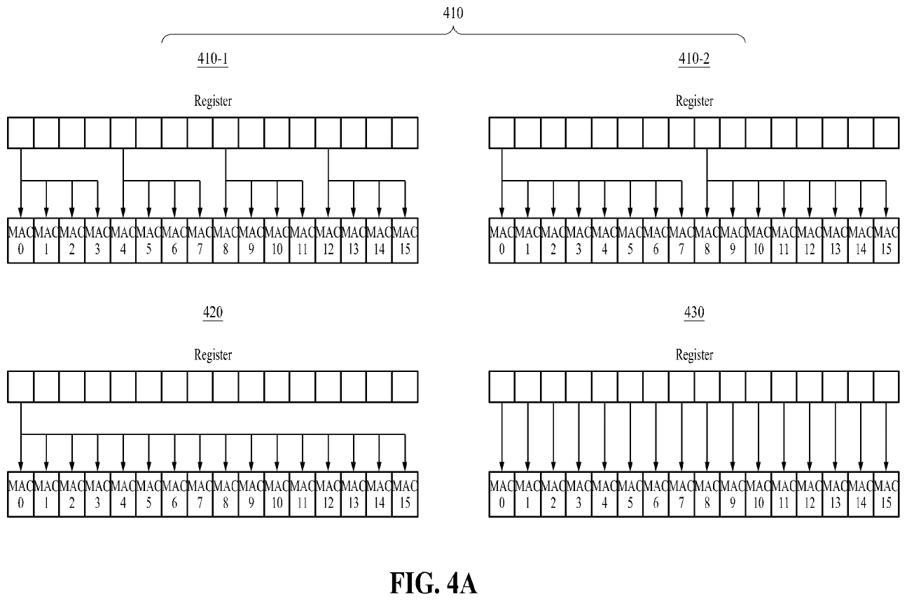

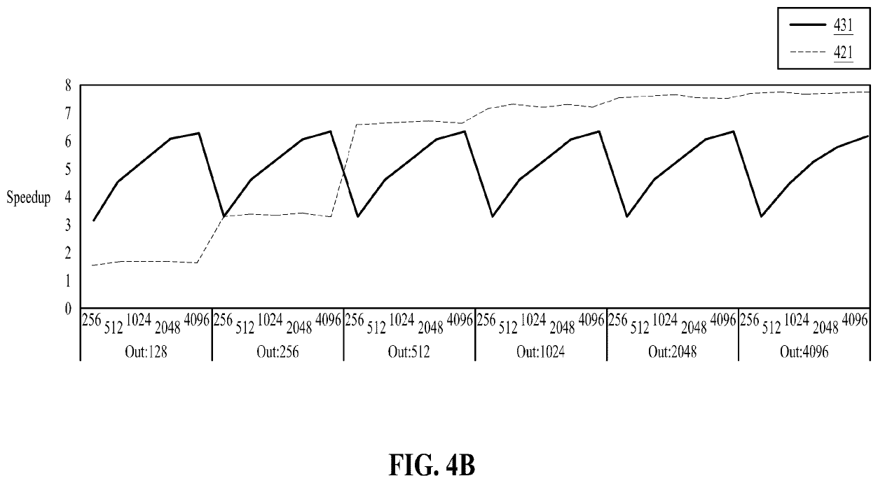

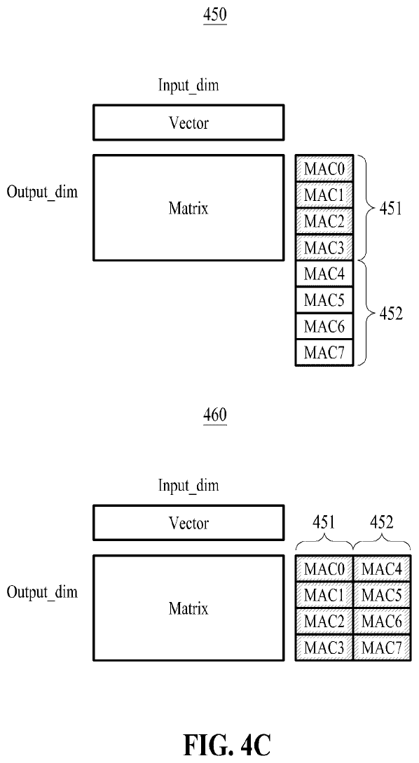

FIGS. 4A to 4C are diagrams illustrating an operation mode according to an embodiment.

Referring to FIG. 4A, an operation mode according to an embodiment may include a first operation mode 410, a second operation mode 420, and a third operation mode 430.

According to the third operation mode 430, a selection module may map a plurality of pieces of data stored in a register to a plurality of operators (e.g., MAC units) in a one-to-one manner. For example, the plurality of operators of the operation module 215 may each receive “N” independent input data (e.g., vector data) as an operand from the register loading “N” elements and may perform an operation (e.g., a MAC operation) between data (e.g., matrix data) read from a memory bank. The plurality of operators may each perform the operation using different input data. The third operation mode 430 may be referred to as a one-to-one mode.

According to the second operation mode 420, the selection module may map any one of the plurality of pieces of data stored in the register to the plurality of operators. The selection module may select one element from the register loading “N” elements and may broadcast the one element to the plurality of operators. The plurality of operators may receive one piece of input data mapped by the selection module as operand data and may perform an operation between operand data read from the memory bank. The second operation mode 420 may be referred to as a one-to-many mode or a broadcast mode.

When performing a GEMV operation on a memory device (e.g., a PIM device) including a PIM block (e.g., the PIM block 121), there may be three factors that impede acceleration. A first factor may be the overhead that occurs when writing an input vector in a host/memory to a register (e.g., the register 211) of the PIM block. A second factor may be the overhead due to an additional operation on the result of the MAC operation in the PIM block. A third factor may be the overhead due to low occupation of MAC operator utilization within the PIM block.

The overheads occurring due to the first and second factors may occur for the same reason. When there are the same number of accumulation registers utilized for the MAC operation, the accumulation registers may be updated every time the MAC operation ends. Here, when the data stored in the accumulation registers is a partial sum, a dimension that may be covered during the MAC operation is bound to decrease. As a result, a frequency in which the register may be reused may decrease, and the same input register may be written multiple times to be used again later, which may be a factor that impedes an acceleration of the MAC operation of the PIM block.

In the third operation mode 430, the data stored in the accumulation register may be in the form of a partial sum, and the magnitude of the partial sum may be N times weighted compared to the final output vector. The memory device may obtain the final output vector through a reduction operation by an additional operation later. In the case of the second operation mode 420, in order to compensate for the above, the memory device may update an accumulation register value in the form of the final output vector rather than in the form of a partial sum. Since the second operation mode 420 stores a reduced value compared to the first operation mode 410, the second operation mode 420 may have a dimension value in many output directions at the same time, thereby achieving a high reuse rate of the register. However, in the case of the second operation mode 420, the dimension of a result vector may be sufficiently large to fully use the MAC operator utilization of the PIM block, and when the dimension of the result vector is below a certain value, performance may be greatly reduced.

Referring to FIG. 4B, a graph 431 shows performance improvement according to a GEMV output dimension and an input dimension when the third operation mode 430 is used, and a graph 421 shows performance improvement according to a GEMV output dimension and an input dimension when the second operation mode 420 is used. In the case of the second operation mode 420, the larger an output dimension, the higher performance is achieved compared to the third operation mode 430, but when the second operation mode 420 is below a certain output dimension, the performance is worse than the third operation mode 430 due to the inability to use all MAC operators.

The first operation mode 410 according to an embodiment is an operation mode that may compensate for the second operation mode 420. According to the first operation mode 410, the selection module is configured to select a plurality of partial pieces of data from among the plurality of pieces of data stored in the register and map the partial pieces of data to the plurality of operators. In the first operation mode 410, the selection module may select two or more and less than “N” pieces of data from a register including “N” stored elements. The first operation mode 410 may be referred to as a partial one-to-many mode or multicast mode.

The first operation mode 410 may have multiple forms depending on the number of partial pieces of data selected by the selection module. For example, “4” pieces of data may be selected by the selection module (e.g., an operation mode 410-1), or “2” pieces of data may be selected by the selection module (e.g., an operation mode 410-2). The number of partial pieces of data selected by the selection module is not limited to the above example.

Referring to FIG. 4C, in the second operation mode 420, the first and second overheads are relatively low among the overheads of the three aspects, but when the output dimension of the matrix data used in the GEMV operation is not sufficiently large, underutilization may occur in the MAC unit of the PIM block.

For example, referring to a diagram 450, in the second operation mode 420, when the output dimension of the matrix data used for the GEMV operation is not large enough, only parts of MAC units 451 among all MAC units are used for the operation and the remaining MAC units 452 may not perform the operation.

On the contrary, the first operation mode 410 may broadcast elements of the register in groups of several parts rather than broadcasting the elements of the register to all the MAC units. Referring to a diagram 460, in the case where underutilization occurs when using the MAC unit of the PIM block, the selection module may map the MAC units 452 that are not performing operations to use other input data as operands. That is, in the first operation mode 410, not only the MAC units 451 participating in the operation in the second operation mode 420 but also the MAC units 452 that do not participate in the operation in the second operation mode 420, may participate in the operation. Accordingly, the memory device operating in the first operation mode 410 may prevent performance degradation even when the output dimension of matrix data is small.

The memory device may support a data operation according to the plurality of operation modes. Based on the current state, the memory device may select an operation mode that provides optimal performance from among the plurality of operation modes. For example, when operating in the third operation mode 430 is more advantageous than operating in the second operation mode 420 because the output dimension is low, the memory device may perform the data operation in the third operation mode 430. On the contrary, when operating in the second operation mode 420 is more advantageous than operating in the third operation mode 430 because the output dimension is high, the memory device may perform the data operation in the second operation mode 420. Alternatively, even if operating in the second operation mode 420 is more advantageous than operating in the third operation mode 430, in the case where underutilization may occur in the MAC unit of the PIM block, the memory device may perform the data operation in the first operation mode 410.

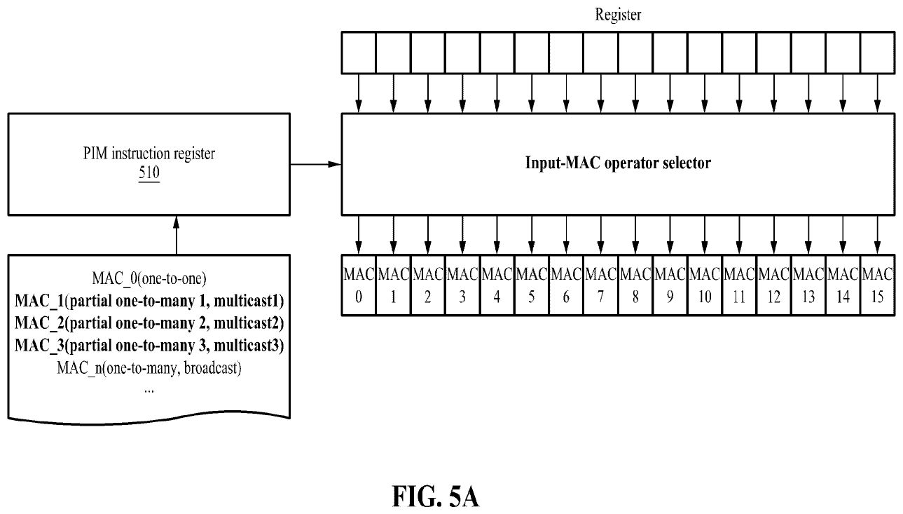

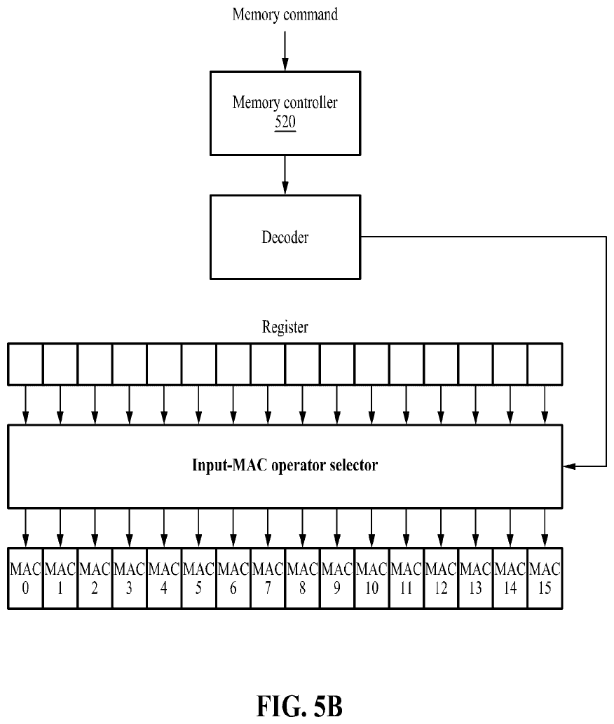

FIG. 5A is a diagram illustrating a method of controlling an operation mode according to a PIM instruction set architecture (ISA) method according to an embodiment.

Referring to FIG. 5A, a PIM block may include a PIM instruction register 510. A PIM instruction register may store a PIM ISA. The PIM ISA includes instructions that the PIM block may execute. The PIM ISA may include an instruction instructing execution of each of a plurality of operation modes.

For example, the PIM ISA may instruct an operation mode with two bits. “01” may instruct a first operation mode using two partial pieces of data, “10” may instruct a first operation mode using four partial pieces of data, “11” may instruct a second operation mode, and “00” may instruct a third operation mode.

A selection module may receive an instruction instructing an operation mode from the PIM instruction register and may map input data of a register to an operation module according to the corresponding operation mode.

FIG. 5B is a diagram illustrating a method of controlling an operation mode according to a method of adding an instruction to a memory controller according to an embodiment.

Referring to FIG. 5B, a memory device according to an embodiment may further include a memory controller 520. The memory controller 520 may transmit an instruction instructing a plurality of operation modes to a selection module. When using the memory controller 520, the plurality of operation modes may be instructed using additional bits (e.g., unused remaining bits) of the instruction when requesting memory. The memory controller 520 may receive a memory command and may transmit additional bits included in the memory command to the selection module through a decoder. The selection module may receive an instruction indicating an operation mode and may map input data of the register to an operation module according to the operation mode.

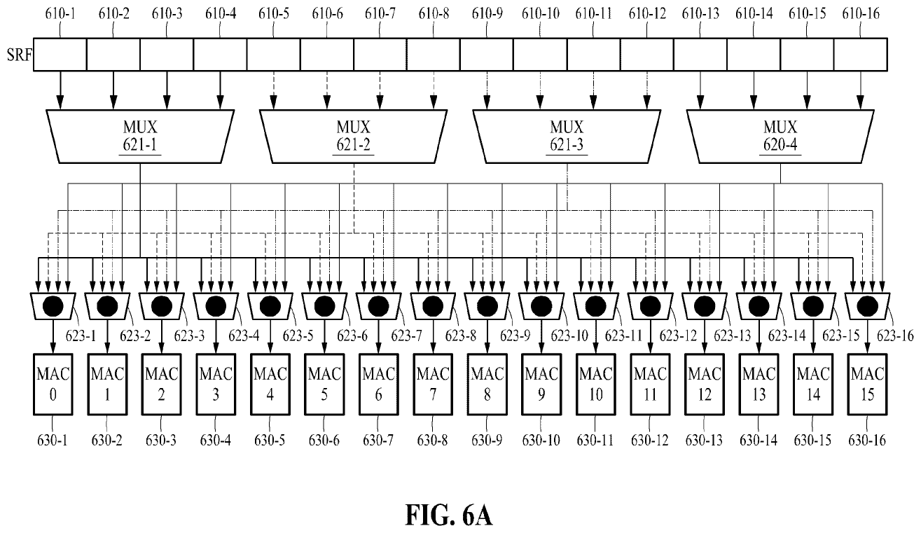

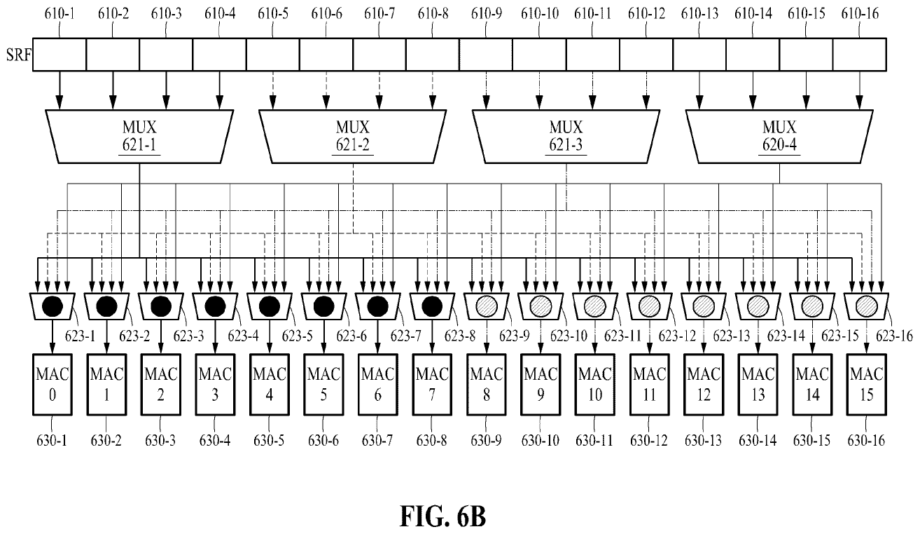

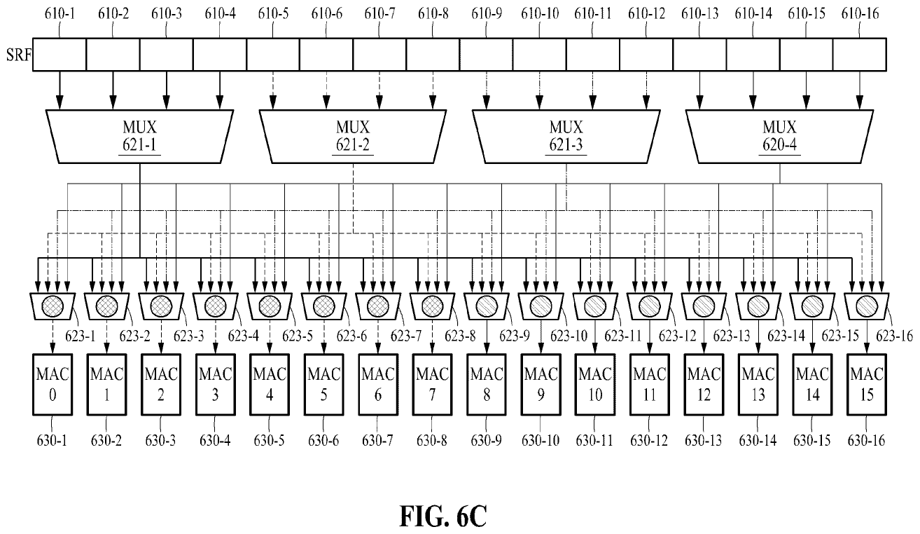

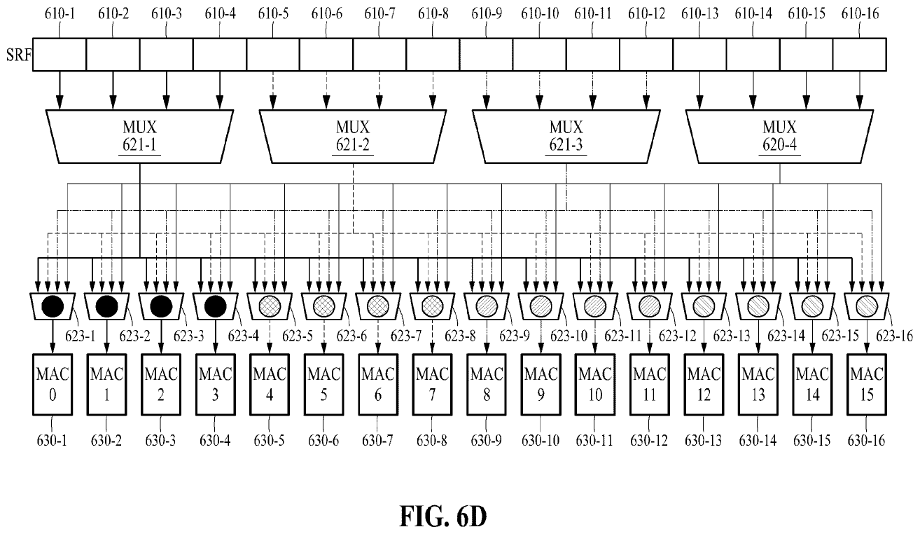

FIGS. 6A to 6D are diagrams illustrating an example of a selection module according to an embodiment.

Referring to FIGS. 6A to 6D, a PIM block according to an embodiment may include a register 610, a selection module 620, and an operation module 630. The register 610 may include a plurality of elements 610-1 to 610-16. The selection module 620 may include first multiplexers 621-1 to 621-4 and second multiplexers 623-1 to 623-16. The operation module 630 may include a plurality of MAC units 630-1 to 630-16. However, the structure of the PIM block shown in FIG. 6 is only an example, and the structure of the PIM block may vary.

Referring to FIG. 6A, in a second operation mode, the PIM block may broadcast one element (e.g., an element 611-1) among a plurality of elements 611-1 to 611-15 to the plurality of MAC units 630-1 to 630-16.

For example, the first multiplexers 621-1 to 621-4 may select one element from the plurality of elements 611-1 to 611-15. For example, the first multiplexer 621-1 may select the element 611-1 from among the elements 611-1 to 611-4 and the first multiplexer 621-2 may select the element 611-5 from among the elements 611-5 to 611-8. The first multiplexer 621-3 may select the element 611-9 from among the elements 611-9 to 611-12 and the first multiplexer 621-4 may select the element 611-13 from among the elements 611-13 to 611-16.

The second multiplexers 623-1 to 623-16 may select one output from among outputs of the first multiplexers 621-1 to 621-4. For example, all of the second multiplexers 623-1 to 623-16 may select the output of the first multiplexer 621-1 from among the outputs of the first multiplexers 621-1 to 621-4. In the second operation mode, the PIM block may broadcast the element 611-1 among the plurality of elements 611-1 to 611-15 to the plurality of MAC units 630-1 to 630-16.

Referring to FIG. 6B, in a first operation mode, the PIM block may multicast two elements from among the plurality of elements 611-1 to 611-15 to the plurality of MAC units 630-1 to 630-16. For example, the PIM block may map the element 611-1 among the plurality of elements 611-1 to 611-15 to the MAC units 630-1 to 630-8 and may map the element 611-9 to the MAC units 630-9 to 630-16. Operators (e.g., MAC units) to which the same elements are mapped may be referred to as an operator set (e.g., a MAC unit set). For example, the MAC units 630-1 to 630-8 may be included in a first MAC unit set and the MAC units 630-9 to 630-16 may be included in a second MAC unit set.

The first multiplexers 621-1 to 621-4 may select one element from the plurality of elements 611-1 to 611-15. For example, an instruction input to a selection module may include “4” bits to select “16” elements. Based on the lower “2” bits of the “4” bits, the first multiplexer 621-1 may select the element 611-1 from among the elements 611-1 to 611-4, the first multiplexer 621-2 may select the element 611-5 from among the elements 611-5 to 611-8, the first multiplexer 621-3 may select the element 611-9 from among the elements 611-9 to 611-12, and the first multiplexer 621-4 may select the element 611-13 from among the elements 611-13 to 611-16.

Parts of the second multiplexers 623-1 to 623-16 may select any one output from among the outputs of the first multiplexers 621-1 to 621-4 and other parts may select another one output from among the outputs of the first multiplexers 621-1 to 621-4. For example, an instruction input to the selection module may include “4” bits to select “16” elements, and among the upper “2” bits of the “4” bits, a least significant bit (LSB) may instruct to select the MAC units 630-1 to 630-8 and a most significant bit (MSB) may instruct to select the MAC units 630-9 to 630-16. That is, the second multiplexers 623-1 to 623-8 may select the output of the first multiplexer 621-1 and the second multiplexers 623-9 to 623-16 may select the output of the first multiplexer 621-3.

In conclusion, in the first operation mode, the PIM block may multicast the element 611-1 and the element 611-9 among the plurality of elements 611-1 to 611-15 to the plurality of MAC units 630-1 to 630-16.

The number of operators included in the operator set may vary based on the first operation mode input. For example, FIG. 6B illustrates a case in which the number of MAC units included in the first MAC unit set and the second MAC unit set are the same, but the number of MAC units included in the MAC unit set may be different. For example, the PIM block may map the element 611-1 among the plurality of elements 611-1 to 611-15 to the MAC units 630-1 to 630-4 and may map the element 611-9 to the MAC units 630-5 to 630-16. In this case, the MAC units 630-1 to 630-4 may form one MAC unit set and the MAC units 630-5 to 630-16 may form another MAC unit set.

For example, an instruction input to the selection module may include “4” bits to select “16” elements, and among the upper “2” bits of the “4” bits, an LSB may instruct to select the MAC units 630-1 to 630-4 and an MSB may instruct to select the MAC units 630-5 to 630-16. That is, the second multiplexers 623-1 to 623-4 may select the output of the first multiplexer 621-1 and the second multiplexers 623-5 to 623-16 may select the output of the first multiplexer 621-3. Referring to FIG. 6C, in the first operation mode, the PIM block may multicast the element 611-5 and the element 611-12 among the plurality of elements 611-1 to 611-15 to the plurality of MAC units 630-1 to 630-16. FIG. 6C differs from FIG. 6B only in that the element 611-5 and the element 611-12 are multicasted instead of the element 611-1 and the element 611-9 and the remaining operations may be applied in the same method as shown in FIG. 6B.

Referring to FIG. 6D, in the first operation mode, the PIM block may multicast “4” elements from among the plurality of elements 611-1 to 611-15 to the plurality of MAC units 630-1 to 630-16. For example, the PIM block may map the element 611-1 among the plurality of elements 611-1 to 611-15 to the MAC units 630-1 to 630-4, may map the element 611-5 to the MAC units 630-5 to 630-8, may map the element 611-9 to the MAC units 630-9 to 630-12, and may map the element 611-13 to the MAC units 630-13 to 630-16.

The first multiplexers 621-1 to 621-4 may select one element from the plurality of elements 611-1 to 611-15. For example, an instruction input to a selection module may include “4” bits to select “16” elements. Based on the lower “2” bits of the “4” bits, the first multiplexer 621-1 may select the element 611-1 from among the elements 611-1 to 611-4, the first multiplexer 621-2 may select the element 611-5 from among the elements 611-5 to 611-8, the first multiplexer 621-3 may select the element 611-9 from among the elements 611-9 to 611-12, and the first multiplexer 621-4 may select the element 611-13 from among the elements 611-13 to 611-16.

The second multiplexers 623-1 to 623-16 may be divided into four parts, and each part may select a different output. For example, an instruction input to the selection module may include “4” bits to select “16” elements, and when the upper “2” bits of the “4” bits are 00, the instruction may instruct to select the MAC units 630-1 to 630-4, when the upper “2” bits are 01, the instruction may instruct to select the MAC units 630-5 to 630-8, when the upper “2” bits are 10, the instruction may instruct to select the MAC units 630-9 to 630-12, and when the upper “2” bits are 11, the instruction may instruct to select the MAC units 630-13 to 630-16. That is, the second multiplexers 623-1 to 623-4 may select the output of the first multiplexer 621-1, the second multiplexers 623-5 to 623-8 may select the output of the first multiplexer 621-2, the second multiplexers 623-9 to 623-12 may select the output of the first multiplexer 621-3, and the second multiplexers 623-13 to 623-16 may select the output of the first multiplexer 621-4.

In FIG. 6D, all of the outputs of the first multiplexers 621-1 to 621-4 are illustrated as being input to the second multiplexers 623-1 to 623-16. However, the output of the first multiplexers 621-1 to 623-4 may be selectively input to the second multiplexers 623-1 to 623-16. For example, the output of the first multiplexer 621-1 may be input only to the second multiplexers 621-1 to 621-4, the output of the first multiplexer 621-2 may be input only to the second multiplexers 621-5 to 621-8, the output of the first multiplexer 621-3 may be input only to the second multiplexers 621-9 to 621-12, and the output of the first multiplexer 621-4 may also be input only to the second multiplexers 621-13 to 621-16.

In the first operation mode, the PIM block may multicast the element 611-1, the element 611-5, the element 611-9, and the element 611-13 among the plurality of elements 611-1 to 611-15 to the plurality of MAC units 630-1 to 630-16.

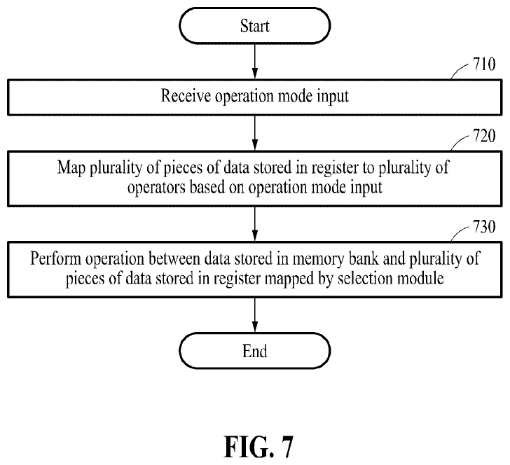

FIG. 7 is a flowchart illustrating a method of operating a memory device according to an embodiment.

For ease of description, operations 710 to 730 are described as being performed using the memory device 120 described with reference to FIG. 1. However, embodiments are not limited thereto. For example, in embodiments, operations 710 to 730 may be performed by another suitable electronic device in a suitable system.

While the operations of FIG. 7 may be performed in the shown order and manner, embodiments are not limited thereto. For example, the order of some operations may be changed or some operations may be omitted without departing from the spirit and scope of embodiments of the present invention. The operations shown in FIG. 7 may be performed in parallel or simultaneously.

In operation 710, the memory device 120 according to an embodiment may receive an operation mode input. An operation mode may include a first operation mode, a second operation mode, and a third operation mode.

In operation 720, the memory device 120 according to an embodiment may map a plurality of pieces of data stored in a register to a plurality of operators based on the operation mode input. The memory device 120 may select a plurality of partial pieces of data from among the plurality of pieces of data stored in the register based on a first operation mode input and may map the partial pieces of data to the plurality of operators. The memory device 120 may map any one of the plurality of pieces of data stored in the register to the plurality of operators based on a second operation mode input. The memory device 120 may map the plurality of pieces of data stored in the register to the plurality of operators in a one-to-one manner based on a third operation mode input.

The memory device 120 may receive an instruction from an instruction register for storing an instruction instructing a plurality of operation modes or may receive an instruction instructing a plurality of operation modes from a memory controller.

In operation 730, the memory device 120 according to an embodiment may perform an operation between data stored in the memory bank and the plurality of pieces of data stored in the register mapped by the selection module.

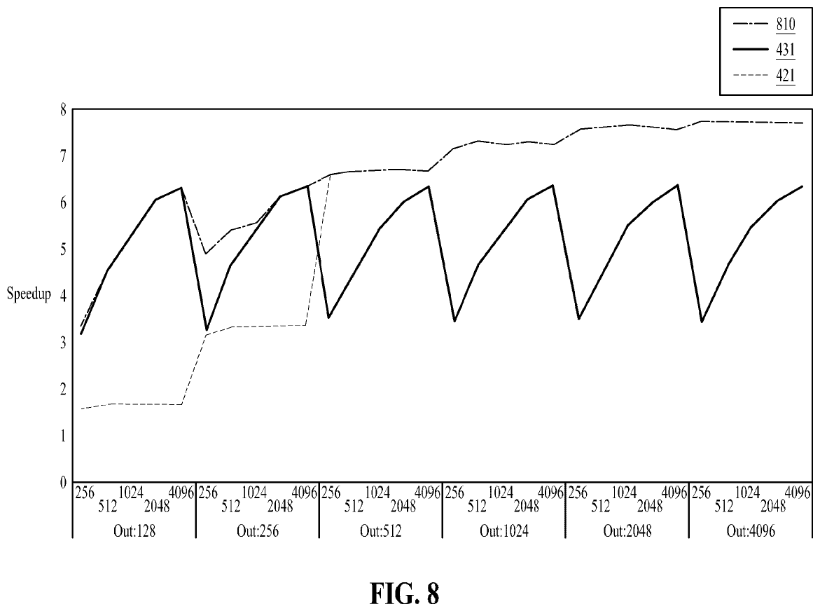

FIG. 8 is a graph illustrating performance of a memory device according to an embodiment.

Referring to FIG. 8, the graph 431 shows performance improvement according to a GEMV output dimension and an input dimension when the third operation mode 430 is used, the graph 421 shows performance improvement according to a GEMV output dimension and an input dimension when the second operation mode 420 is used, and a graph 810 shows performance improvement according to a GEMV output dimension and an input dimension when a method of selecting the plurality of operation modes is used.

Referring to the graph 810, it may be noted that better performance is obtained when the method of selecting the plurality of operation modes is used compared to when only the third operation mode 430 is used and when only the second operation mode 420 is used.

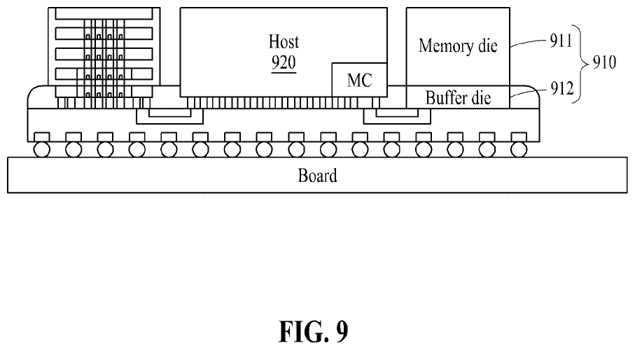

FIG. 9 illustrates a high bandwidth memory (HBM) device according to an embodiment.

A memory device 910 according to an embodiment may be implemented as an HBM device. For example, the memory device 910 may include a memory die 911 and a buffer die 912. The memory device 910 may be disposed adjacent to a host 920 having a memory controller. The memory device 910 may perform dynamic mapping between input data in a register and a MAC unit, as described above with reference to FIGS. 1 to 7.

However, the memory device 910 is not limited to the embodiments described above. For example, the memory device 910 may be implemented as a low-power double data rate (LPDDR) device, a graphics double data rate (GDDR) device, or a double data rate (DDR) device, in addition to an HBM device. A computing system 900 including the host 920 and the memory device 910 may perform machine learning. Machine learning may include artificial intelligence (AI) and deep neural networks (DNNs). However, embodiments are not limited thereto. For example, the computing system 900 may execute a camera application according to embodiments. The computing system 900 may also be implemented as a wearable device according to embodiments.

The embodiments described herein may be implemented using a hardware component, a software component and/or a combination thereof. A processing device may be implemented using one or more general-purpose or special-purpose computers, such as, for example, a processor, a controller and an arithmetic logic unit (ALU), a digital signal processor (DSP), a microcomputer, a field-programmable gate array (FPGA), a programmable logic unit (PLU), a microprocessor or any other device capable of responding to and executing instructions in a defined manner. The processing device may run an operating system (OS) and one or more software applications that run on the OS. The processing device also may access, store, manipulate, process, and generate data in response to execution of the software. For purpose of simplicity, the description of a processing device is used as singular; however, one skilled in the art will appreciate that a processing device may include multiple processing elements and multiple types of processing elements. For example, a processing device may include multiple processors or a processor and a controller. In addition, different processing configurations are possible, such as parallel processors.

The software may include a computer program, a piece of code, an instruction, or combinations thereof, to independently or uniformly instruct or configure the processing device to operate as desired. Software and/or data may be embodied permanently or temporarily in any type of machine, component, physical or virtual equipment, computer storage medium or device, or in a propagated signal wave capable of providing instructions or data to or being interpreted by the processing device. The software may also be distributed over network-coupled computer systems so that the software is stored and executed in a distributed fashion. The software and data may be stored in a non-transitory computer-readable recording medium.

The methods according to the above-described embodiments may be recorded in non-transitory computer-readable media including program instructions to implement various operations of the above-described embodiments. The media may also include, alone or in combination with the program instructions, data files, data structures, and the like. The program instructions recorded on the media may be those specially designed and constructed for the purposes of embodiments, or they may be of the kind well-known and available to those having skill in the computer software arts. Examples of non-transitory computer-readable media include magnetic media such as hard disks, floppy disks, and magnetic tape; optical media such as CD-ROM discs or DVDs; magneto-optical media such as optical discs; and hardware devices that are specially configured to store and perform program instructions, such as read-only memory (ROM), random access memory (RAM), flash memory, and the like. Examples of program instructions include both machine code, such as produced by a compiler, and files containing higher-level code that may be executed by the computer using an interpreter.

As is traditional in the field of the present invention, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, etc., which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions.

While the present invention has been particularly shown and described with reference to embodiments thereof, it will be understood by those of ordinary skill in the art that various changes in form and detail may be made therein without departing from the spirit and scope of the present invention as defined by the following claims.

What is claimed is:

1. A memory device for supporting a data operation according to a plurality of operation modes, the memory device comprising:
an operation module including a plurality of operators configured to perform the data operation;
a register configured to store a plurality of pieces of data; and
a selection module configured to receive an operation mode input and map the plurality of pieces of data stored in the register to the plurality of operators based on the operation mode input.

2. The memory device of claim 1, wherein
the selection module is further configured to select a plurality of partial pieces of data from among the plurality of pieces of data stored in the register based on the operation mode input and map the partial pieces of data to the plurality of operators.

3. The memory device of claim 2, wherein
the selection module is further configured to map each of the plurality of partial pieces of data to a different set of operators based on the operation mode input.

4. The memory device of claim 3, wherein
a number of operators included in the set of operators is variable based on the operation mode input.

5. The memory device of claim 1, wherein
the selection module is further configured to map any one of the plurality of pieces of data stored in the register to the plurality of operators based on the operation mode input.

6. The memory device of claim 1, wherein
the selection module is further configured to map the plurality of pieces of data stored in the register to the plurality of operators in a one-to-one manner based on the operation mode input.

7. The memory device of claim 1, further comprising:
a memory bank,
wherein the operation module is configured to perform an operation between data stored in the memory bank and the plurality of pieces of data stored in the register mapped by the selection module.

8. The memory device of claim 7, wherein
the memory bank is configured to store matrix data,
wherein the register is configured to store a plurality of pieces of vector data, and
wherein the operation module is configured to perform a multiply and accumulate (MAC) operation between the matrix data and the plurality of pieces of vector data.

9. The memory device of claim 8, wherein
the plurality of operation modes is determined based on at least one of a dimension of the matrix data, a dimension of the plurality of pieces of vector data, or a number of the plurality of operators included in the operation module.

10. The memory device of claim 8, wherein
the memory bank is configured to store weight data of an artificial neural network model,
wherein the register is configured to store input data of the artificial neural network model.

11. The memory device of claim 1, further comprising:
an instruction register configured to store an instruction instructing the plurality of operation modes,
wherein the selection module is further configured to receive the instruction from the instruction register.

12. The memory device of claim 1, further comprising:
a memory controller configured to transmit an instruction instructing the plurality of operation modes to the selection module.

13. The memory device of claim 1, wherein
the plurality of pieces of data stored in the register is divided into a plurality of parts,
wherein the selection module comprises:
a plurality of first multiplexers configured to output, for each of the plurality of parts, any one of pieces of data included in a corresponding part; and
a plurality of second multiplexers configured to be mapped to each of the plurality of operators,
wherein, for each of the second multiplexers, a corresponding second multiplexer is configured to output any one of pieces of data received from the first multiplexers to an operator mapped to the corresponding second multiplexer.

14. The memory device of claim 1, wherein
the memory device is implemented as one of a high bandwidth memory (HBM) device, a double data rate (DDR) device, a low-power double data rate (LPDDR) device, or a graphics double data rate (GDDR) device.

15. A memory device, comprising:
an operation module including a plurality of operators configured to perform a data operation;
a memory bank configured to store matrix data;
a register configured to store a plurality of pieces of vector data; and
a selection module configured to select a plurality of partial pieces of data from among the plurality of pieces of vector data stored in the register and map the partial pieces of data to the plurality of operators, based on a dimension of the matrix data and a number of the plurality of operators included in the operation module.

16. A method of operating a memory device for supporting a data operation according to a plurality of operation modes, the method comprising:
receiving an operation mode input;
mapping a plurality of pieces of data stored in a register to a plurality of operators based on the operation mode input; and
performing an operation between data stored in a memory bank and the plurality of pieces of data stored in the register and mapped by a selection module.

17. The method of claim 16, wherein
the mapping of the plurality of pieces of data to the plurality of operators comprises:
selecting a plurality of partial pieces of data from among the plurality of pieces of data stored in the register based on the operation mode input; and
mapping the partial pieces of data to the plurality of operators.

18. The method of claim 16, wherein
the mapping of the plurality of pieces of data to the plurality of operators comprises mapping any one of the plurality of pieces of data stored in the register to the plurality of operators based on the operation mode input.

19. The method of claim 16, wherein
the mapping of the plurality of pieces of data to the plurality of operators comprises mapping the plurality of pieces of data stored in the register to the plurality of operators in a one-to-one manner based on the operation mode input.

20. The method of claim 16, wherein
the mapping of the plurality of pieces of data to the plurality of operators comprises receiving an instruction from an instruction register configured to store the instruction instructing the plurality of operation modes.

21. The method of claim 16, wherein
the mapping of the plurality of pieces of data to the plurality of operators comprises receiving an instruction instructing the plurality of operation modes from a memory controller.
